(19) United States
(12) Patent Application Publication
(10) Pub. No.: US 2008/0197390 A1
(43) Pub. Date: Aug. 21, 2008

(54) SEMICONDUCTOR APPARATUS AND METHOD FOR MANUFACTURING SEMICONDUCTOR APPARATUS

(75) Inventor: Yuki YAMADA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/035,002

(22) Filed: Feb. 21, 2008

(30) Foreign Application Priority Data
Feb. 21, 2007 (JP) 2007-041221

(51) Int. Cl. H01L 27/115; H01L 21/8246

(52) U.S. Cl. 257/295; 438/3; 257/E27.104; 257/E21.664; 257/E21.648

(57) ABSTRACT

According to an aspect of the present invention, there is provided a semiconductor apparatus including: a semiconductor substrate; a transistor including: a first diffusion layer formed on the semiconductor substrate, and a second diffusion layer formed on the semiconductor substrate; a ferroelectric capacitor including: a bottom electrode connected to the first diffusion layer, a ferroelectric film formed on the bottom electrode, and a top electrode formed on the ferroelectric film; a side wall disposed on a side surface of the ferroelectric capacitor, the side wall having a lower end positioned upper than a bottom plane of the ferroelectric capacitor; and a contact plug connected to the second diffusion layer and to the top electrode, the contact plug being in touch with the side wall.

### CROSS-REFERENCE TO RELATED APPLICATIONS

The entire disclosure of Japanese Patent Application No. 2007-041221 filed on Feb. 21, 2007 including specification, claims, drawings and abstract is incorporated herein by reference in its entirety.

### BACKGROUND OF THE INVENTION

1. Field of the Invention

An aspect of the present invention relates to a semiconductor apparatus including a ferroelectric capacitor and a method for manufacturing such semiconductor apparatus.

2. Description of the Related Art

There is known a semiconductor apparatus for storing data in a non-volatile manner using a ferroelectric material (which is hereinafter referred to as FeRAM, Ferroelectric RandomAccess Memory). As a structure of the FeRAM, a Chain-FeRAM™ structure is proposed. In the Chain-FeRAM™, a transistor and a ferroelectric capacitor is connected in parallel to each other; and a plurality of such sets are connected in series to each other to thereby constitute a cell array block. The ferroelectric capacitor can be formed in such a manner that a bottom electrode, a ferroelectric film and a top electrode are sequentially laminated on a semiconductor substrate through an insulating film.

In the Chain-FeRAM™, owing to common use of the diffusion layers of the adjoining transistors within the cell array block and also owing to use of a COP (Capacitor On Plug) structure in the ferroelectric capacitor, miniaturization of the unit cell of the FeRAM can be can be enhanced. The COP structure is a structure that a contact plug is formed in an inter-layer insulting film formed on a semiconductor substrate on top of which a transistor is provided and a ferroelectric capacitor is formed on the contact plug.

Also, as a structure aiming at miniaturizing a cell, there is disclosed a semiconductor apparatus in which side wall insulating films (side walls) are formed in both respective side surfaces of a ferroelectric capacitor, and in which a contact plug is self-alignably formed with the side walls (For example, see JP-A-2004-311703).

However, since the side walls are formed to cover the side surfaces of the ferroelectric capacitor respectively ranging from the upper surface thereof to the lower surface thereof, an opening formed between the adjoining side walls decreases in width as it goes toward the lower surface. As a result of this, there is raised a problem that the diameter of a contact plug (serving as a current passage) to be formed in the opening becomes small.

### SUMMARY OF THE INVENTION

According to an aspect of the present invention, there is provided a semiconductor apparatus including: a semiconductor substrate; a transistor including: a first diffusion layer formed on the semiconductor substrate, and a second diffusion layer formed on the semiconductor substrate; a ferroelectric capacitor including: a bottom electrode connected to the first diffusion layer, a ferroelectric film formed on the bottom electrode, and a top electrode formed on the ferroelectric film; a side wall disposed on a side surface of the ferroelectric capacitor, the side wall having a lower end positioned upper than a bottom plane of the ferroelectric capacitor; and a contact plug connected to the second diffusion layer and to the top electrode, the contact plug being in touch with the side wall.

According to another aspect of the present invention, there is provided a method for manufacturing a semiconductor apparatus, the method including: forming a transistor having a first and a second diffusion layers on a semiconductor substrate; forming a first interlayer insulating film on the semiconductor substrate; forming a first and a second contact plugs respectively connected to the first and the second diffusion layers and disposed in the first interlayer insulating film; forming a ferroelectric capacitor having a reaction preventive film disposed on the first interlayer insulating film and connected to the first contact plug, a bottom electrode formed on the reaction preventive film, a ferroelectric film formed on the bottom electrode, a top electrode formed on the ferroelectric film, and an upper film formed on the top electrode, by: sequentially forming a reaction preventive film material, a bottom electrode material, a ferroelectric film material, a top electrode material and an upper film material, on the first interlayer insulating film, patterning the upper film material so as to be used as a mask, and performing an etching process using the mask; forming a reaction preventive insulating film on the whole surface where the ferroelectric capacitor is formed; forming a second interlayer insulating film on the reaction preventive insulating film; adjusting the second interlayer insulating film so that a top surface thereof is situated at a level between an upper and a lower surfaces of the ferroelectric capacitor and so that the second interlayer insulating film is hardly left on the top electrode by performing a first etching-back process; forming a side wall material on the whole surface where the first etching-back process is performed; forming a side wall on a side surface of the ferroelectric capacitor by performing a second etching-back process; forming a third interlayer insulating film on the whole surface where the second etching-back process is performed; and forming a third contact plug connected to the second contact plug in the third interlayer insulating film, the third contact plug being in touch with the side wall.

### BRIEF DESCRIPTION OF THE DRAWINGS

Embodiments may be described in detail with reference to the accompanying drawings, in which:

FIG. 1 is a schematic section view of a semiconductor apparatus according to an embodiment 1;

FIGS. 2A and 2B are schematic section views each showing a step of a method for manufacturing the semiconductor apparatus according to the embodiment 1;

FIGS. 3A and 3B are schematic section views, continuously with FIGS. 2A and 2B, each showing a step of a method for manufacturing the semiconductor apparatus according to the embodiment 1;

FIGS. 4A and 4B are schematic section views, continuously with FIGS. 3A and 3B, each showing a step of a method for manufacturing the semiconductor apparatus according to the embodiment 1;

FIG. 5 is a schematic section view, continuously with FIGS. 4A and 4B, showing a step of a method for manufacturing the semiconductor apparatus according to the embodiment 1;

FIG. 6 is a schematic section view of a semiconductor apparatus according to an embodiment 2;

FIG. 7 is a schematic section view of a semiconductor apparatus according to an embodiment 3;

FIG. 8 is a schematic section view of a semiconductor apparatus according to an embodiment 4; and

FIG. 9 is a schematic section view of a semiconductor apparatus according to an embodiment 5.

### DETAILED DESCRIPTION OF THE INVENTION

Description will be given below of embodiments with reference to the accompanying drawings. In the respective figures, elements having the same structure are given the same designations.

### Embodiment 1

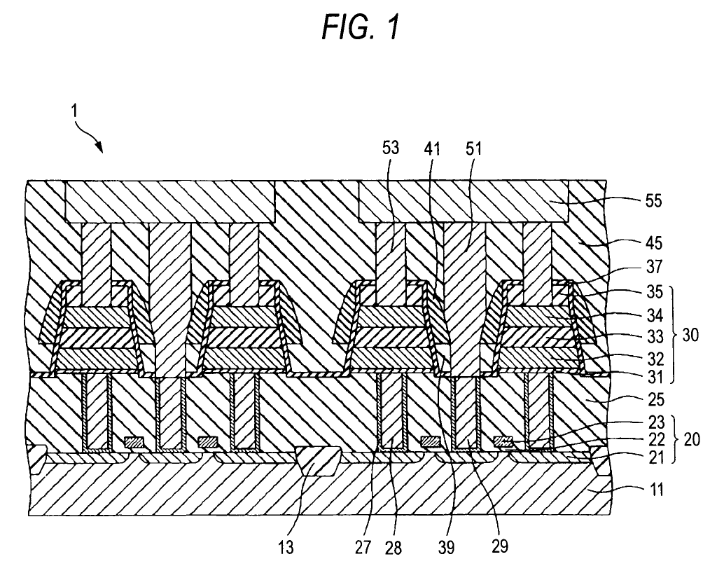

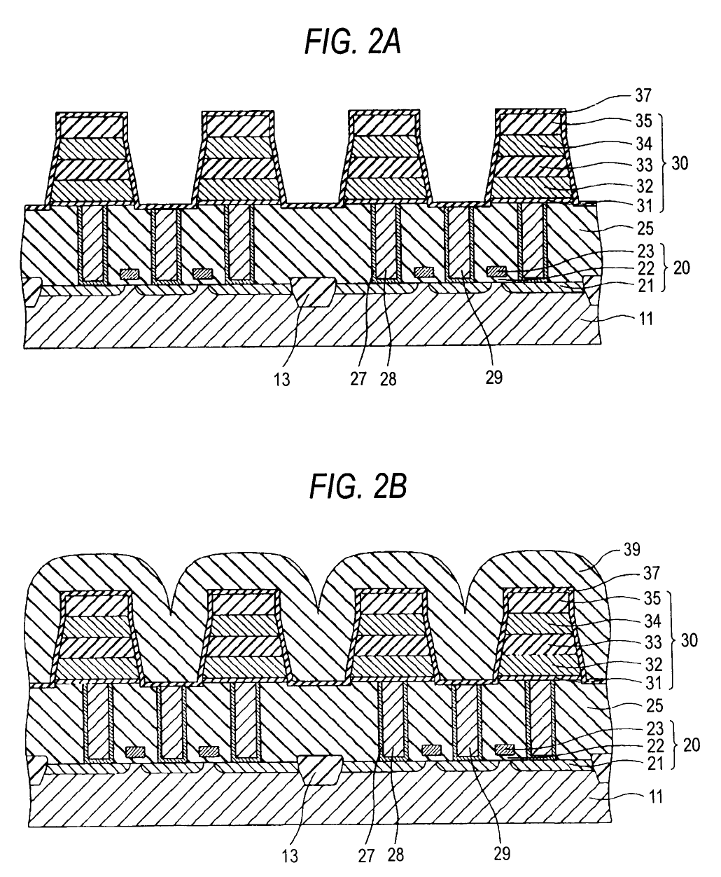

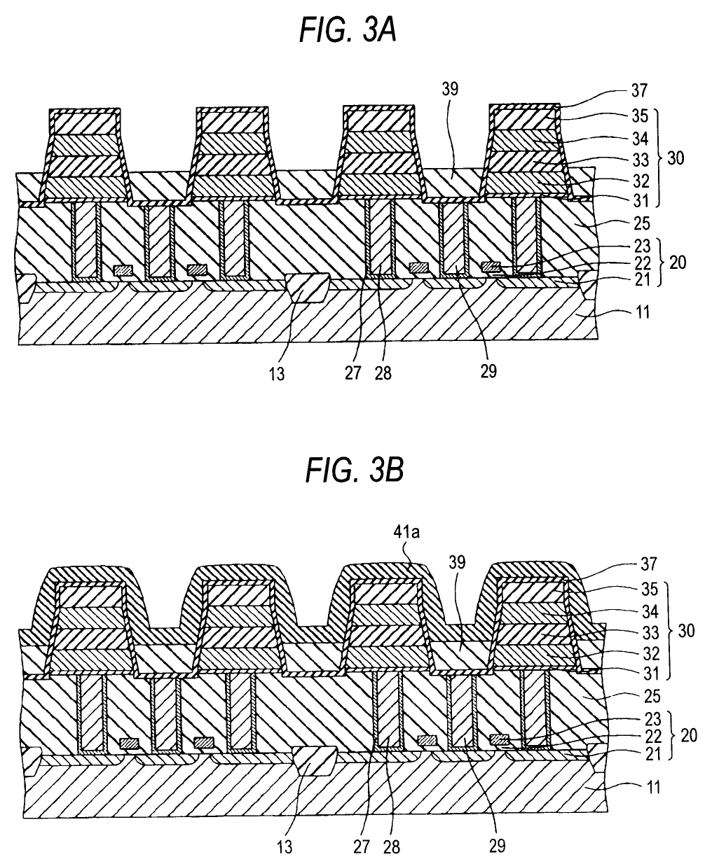

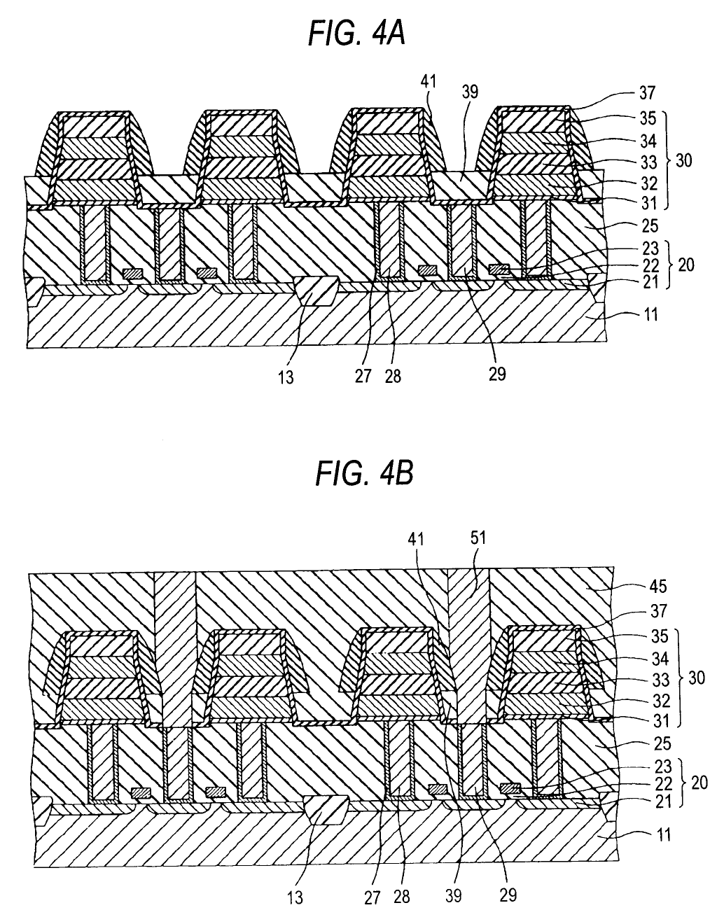

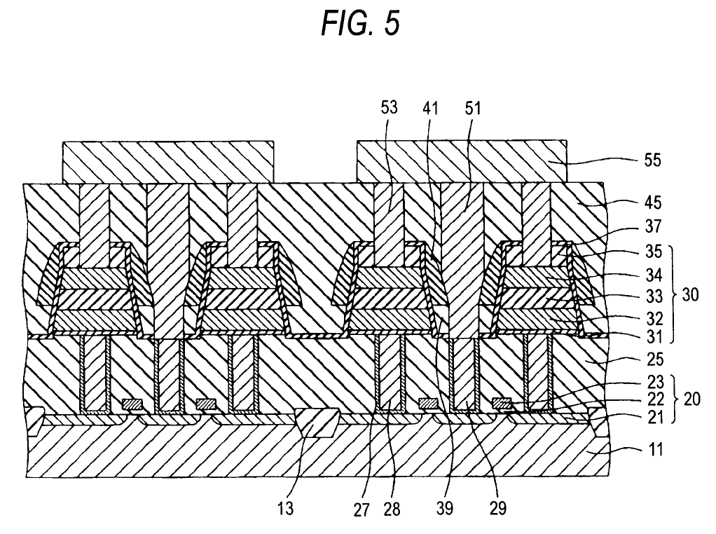

Description will be given below of a semiconductor apparatus and a method for manufacturing a semiconductor apparatus according to an embodiment 1 with reference to FIGS. 1 to 5. FIG. 1 is a schematic section view of the structure of a semiconductor apparatus. FIGS. 2A and 2B are schematic section views each showing a step of method for manufacturing the semiconductor apparatus. FIGS. 3A and 3B are schematic section views, continuously with FIGS. 2A and 2B, each showing a step of a method for manufacturing the semiconductor apparatus. FIGS. 4A and 4B are schematic section views, continuously with FIGS. 3A and 3B, each showing a step of a method for manufacturing the semiconductor apparatus. FIG. 5 is a schematic section view, continuously with FIGS. 4A and 4B, showing a step of a method for manufacturing the semiconductor apparatus.

As shown in FIG. 1, a semiconductor apparatus 1 includes a semiconductor substrate 11; a transistor 20 disposed on the semiconductor substrate 11; a ferroelectric capacitor 30 including a reaction preventive film 31, a bottom electrode 32, a ferroelectric film 33 and a top electrode 34 sequentially, with the reaction preventive film 31 being connected to the transistor 20 and the top electrode 34 being connected to a wiring 55; a side wall 41 disposed on a side surface of the ferroelectric capacitor 30, having a lower end situated at a position upper than the lowest position of the ferroelectric capacitor 30; and, a third contact plug 51 having the upper end connected to the wiring 55 and the lower end connected to the transistor 20 through a second contact plug 29, the third contact plug 51 being in touch with the side wall 41.

The semiconductor substrate 11 is, for example, a silicone substrate which has a p-type element forming area. On the surface of the semiconductor substrate 11, there is formed an element forming area which is divided into divisional areas by an element separating area 13. In the element forming area, there are formed two n-type diffusion layers 21 which function as a source and a drain. Between the paired diffusion layers 21, a gate electrode 23 is formed on the silicon substrate through a gate insulating film 22, thereby constituting the transistor 20.

The ferroelectric capacitor 30 is structured such that the reaction preventive film 31, the bottom electrode 32, the ferroelectric film 33, the top electrode 34 and the upper film 35 are laminated sequentially. The reaction preventive film 31 is a lowest side thereof. The reaction preventive film 31 is a conductive film which is formed in order to prevent oxygen against reaction or diffusion. The reaction preventive film 31 is connected through a first contact plug 28 to one of the diffusion layers 21 of the transistor 20. The top electrode 34 is connected through a fourth contact plug 53 to the wiring 55. The upper film 35 is a hard mask which still remains even after the ferroelectric capacitor 30 is worked. However, the upper film 35 may be omitted. The wiring 55 is connected through the second and third contact plugs 29 and 51 to the other diffusion layer 21 of the transistor 20.

A cell used as the unit of a memory is composed of one ferroelectric capacitor 30 and one transistor 20 which is to be connected to the ferroelectric capacitor 30 and has a switching function. The second and third contact plugs 29 and 51 are commonly used by adjoining cells, are connected to each of the adjoining ferroelectric capacitors 30, and are interposed between the two adjoining ferroelectric capacitors 30.

Referring to the structure of the ferroelectric capacitor 30, the side surface thereof is formed perpendicularly to or at an angle smaller than 90 degrees to the semiconductor substrate 11; and the side surface and the upper surface thereof (whole surface of the ferroelectric capacitor 30 except for the lower surface of the reaction preventive film 31) is covered with a hydrogen barrier film 37 which is a reaction preventive insulating film to prevent the ferroelectric film 33 against hydrogen damage.

On the side surface of the ferroelectric capacitor 30, there is provided the side wall 41 made of an insulating film through the hydrogen barrier film 37. The side wall 41 has an upper end face situated at a position almost flush with the upper surface of the hydrogen barrier film 37 disposed on the upper surface of the ferroelectric capacitor 30 and a lower end face situated at a position upper than the lower plane of the bottom electrode 32. The side surface of the side wall 41 overhangs more and more from the vertical center line of the ferroelectric capacitor 30 as it approaches its lower end face. That is, the distance between such side surface and the side surface of the adjoining side wall 41 decreases as the lower end edge of the sidewall 41 approaches the bottom electrode 32. Between the lower end face of the side wall 41 and the lower hydrogen barrier film 37, there is interposed a second inter-layer insulating film 39.

The first and second contact plugs 28 and 29 respectively include conductive contact reaction preventive films 27 on their respective outer surfaces, and are respectively formed in a first inter-layer insulating film 25. The third contact plug 51 penetrates through a third inter-layer insulating film 45, second inter-layer insulating film 39 and hydrogen barrier film 37, while the two ends of the third contact plug 51 are connected to the wiring 55 and second contact plug 29 respectively. The wiring 55 side (the upper side) of the third contact plug 51 has a constant width shape or a tapered shape. The lower side middle portion of the third contact plug 51 being in touch with the side wall 41 decreases in width along the shapes of the side surfaces of the side walls 41 on both sides. Below the lower end portion of the side wall 41, the third contact plug 51 has a constant width in the above width-decreased state and is connected to the upper end of the second contact plug 29. The fourth contact plug 53 penetrates through the third inter-layer insulating film 45, hydrogen barrier film 37 and upper film 35.

Description will be given below of a method for manufacturing the semiconductor apparatus 1. As shown in FIG. 2A, the transistor 20 to be provided on the semiconductor substrate 11 can be formed according to a well-known method. The first inter-layer insulating film 25 is formed so as to cover the transistor 20. In the first inter-layer insulating film 2S, there is formed a contact hole first; and, in the contact hole, there are formed the conductive contact reaction preventive film 27 and then a conductive contact plug film (material for forming a contact plug) according to a sputtering method, a CVD (Chemical Vapor Deposition) method, or the like. After then, the surfaces thereof are flattened according to a CMP (Chemical Mechanical Polishing) method, or the like to thereby provide the first and second contact plugs 28 and 29. The first inter-layer insulating film 25 can be formed by using, for example, BPSG (Boron Phosphorous Silicate Glass) or TEOS (Plasma-Tetra Ethoxy Silane) according to a DF-PECVD (Dual Frequency-Plasma Enhanced CVD) method. The contact reaction preventive film 27 can be formed by using, for example, Ti, TiN, or the like, while the contact plug film can be formed by using, for example, W, Al—Cu, polycrystal silicone, or the like. The contact reaction preventive film 27 is formed in order to prevent metal, or the like constituting the contact plug film from reacting with H₂O existing therearound, or reacting with the diffusion layer 21 of the transistor 20.

Next, onto the first inter-layer insulating film 25 as well as the first and second contact plugs 28 and 29, there are sequentially laminated material films, which are used to form the ferroelectric capacitor 30, namely, a second reaction preventive film, a bottom electrode film, a ferroelectric film, a top electrode film and a hard mask film. The hard mask film is functioning as a hard mask for processing the ferroelectric capacitor 30. The second reaction preventive film can be formed by using, for example, Ir, IrO₂, TiAlN, Ru, RuO₂, or the like. The bottom and the top electrode films can be formed by using, for example, Pt, Ir, IrO₂, SRO (Strontium Ruthenium Oxide), Ru, RuO₂, or the like. The ferroelectric film can be formed by using, for example, PZT (Pb (Zr, Ti) O₃), SBT (SrBi₂Ta₂O₉), or PZLT ((Pb, La) (Zr, Ti) O₃). The hardmask film can be formed by using, for example, Al₂O₃, TiAlN, TEOS, or the like. The second reaction preventive film is formed in order to prevent the diffusion of oxygen.

Next, the hard mask film is patterned to form the hard mask and, a reactive ion etching (RIE) processing using ArCl, CF₄, or the like is performed, whereby the ferroelectric capacitor 30 including the upper film 35, the top electrode 34, the ferroelectric film 33, the bottom electrode 32 and the reaction preventive film 31 is formed.

Next, on the ferroelectric capacitor 30, first inter-layer insulating film 25 and second contact plug 29, there is formed the hydrogen barrier film 37 according to an ALD (Atomic Layer Deposition) method, the sputtering method, or the like. The hydrogen barrier film 37 is made of, for example, Al₂O₃, SiN, or the like, and it provides an effect to prevent the ferroelectric film 33 against hydrogen damage.

As shown in FIG. 2B, on the hydrogen barrier film 37, there is formed a second inter-layer insulating film 39. The second inter-layer insulating film 39 can be formed by using BPSG, TEOS, or the like according to the above-mentioned method. The film thickness of the second inter-layer insulating film 39 is adjusted so that, when the etching-back step (next step) is performed, on the upper surface of the ferroelectric capacitor 30, most of the inter-layer insulating film 39 is removed, and, on the second contact plug 29, the lower end face of the inter-layer insulating film 39 is left up to a position that is higher than the bottom electrode 32 of the ferroelectric capacitor 30.

As shown in FIG. 3A, the second inter-layer insulating film 39 is etched back according to a RIE method, or the like; and the second inter-layer insulating film 39 is left in the vicinity of the side surface of the ferroelectric capacitor 30 up to a position of the side of the ferroelectric capacitor 30 that is higher than the lower end face thereof. On the upper surface of the ferroelectric capacitor 30 and in the vicinity of the upper side surface of the ferroelectric capacitor 30, most of the second inter-layer insulating film 39 is removed therefrom. In this case, most of the hydrogen barrier film 37 is left after etching-back is performed.

As shown in FIG. 3B, on the upper and side surfaces of the ferroelectric capacitor 30 as well as on the second inter-layer insulating film 39, a side wall insulating film 41a is formed by using a P-CVD method, an ALD method, or the like. The side wall insulating film 41a can be made of, for example, SiN, Al₂O₃, SiON, TiO₂, or the like. The hydrogen barrier film 37 prevents the ferroelectric capacitor 30 from the damage caused by forming the side wall insulating film 41a and from the deterioration caused by the infiltration of hydrogen generated in the following steps.

As shown in FIG. 4A, the side wall insulating film 41a is etched back by a RIE method, or the like, whereby the side wall 41 is formed. The side wall 41 is structured such that the upper end face thereof is almost flush with the surface of the hydrogen barrier film 37 placed on the upper surface of the ferroelectric capacitor 30, while the lower end face thereof is situated on the upper surface of the second inter-layer insulating film 39 provided on the side surface of the ferroelectric capacitor 30.

As shown in FIG. 4B, on the upper surface of the side wall 41 and the like, the third inter-layer insulating film 45 is formed; and, after the third inter-layer insulating film 45 is flattened by a CMP method, or the like, the third contact plug 51 is formed in a self-aligning manner. That is, on the surface of the flattened third inter-layer insulating film 45, there is formed a mask which is patterned according to a photolithographic method; based on the patterned mask, there is formed a contact hole such that it penetrates through the third inter-layer insulating film 45, second inter-layer insulating film 39 and hydrogen barrier film 37; and, in the contact hole, there is formed a conductive contact plug film (material for forming a contact plug) according to a sputtering method, a CVD method, or the like, thereby forming the third contact plug 51 that is connected to the second contact plug 29. Even if the contact hole formed according to the photolithographic method is shifted slightly in position, the contact hole is dug in a self-aligning manner along the side wall 41 so as to penetrate through the third inter-layer insulating film 45; and, from the lower end portion of the side wall 41, the contact hole is formed almost in the vertical direction so as to penetrate through the second inter-layer insulating film 39 and hydrogen barrier film 37. The third inter-layer insulating film 45 can be formed according to, for example, the above-mentioned BPSG method, TEOS method, or the like. The contact plug film, which constitutes the third contact plug 51, can be formed by using, for example, W, Al—Cu, poly-crystalline silicone, or the like. Since the contact hole is formed in a self-aligning manner along the side wall 41, it can be connected to the second contact plug 29 while avoiding a risk of occurrence of a short circuit between the top and the bottom electrodes 34 and 32 of the ferroelectric capacitor 30.

As shown in FIG. 5, after the formation of the third contact plug 51, the upper surface of the third inter-layer insulating film 45 is flattened according to a CMP method, or the like. After then, similarly to the formation of the third contact plug 51, there is formed the fourth contact plug 53 such that it penetrates through the third inter-layer insulating film 45, hydrogen barrier film 37 and upper film 35. After then, the upper surface of the third inter-layer insulating film 45 is flattened according to a CMP method, or the like; and, there is formed the wiring 55 that is connected to the third and fourth contact plugs 51 and 53. The contact plug film to constitute the fourth contact plug 51 can be formed by using, for example, W, Al—Cu, poly-crystalline silicone, or the like; and, the wiring 55 can be formed by using, for example, Al, W, Cu, or the like. Here, there has been shown an example in which the third contact plug 51 is formed prior to the formation of the fourth contact plug 53. However, it is also possible to form the fourth contact plug 53 before the third contact plug 51 is formed.

Steps, which are to be executed after the formation of the wiring 55, are similar to a generally used semiconductor manufacturing method. As a result of this, the semiconductor apparatus 1 is completed as shown in FIG. 1.

As described above, the semiconductor apparatus 1 includes: the transistor 20 provided on the semiconductor substrate 11; a ferroelectric capacitor 30 in which the bottom electrode 32 is connected through the first contact plug 28 to the transistor 20 and the top electrode 34 is connected through the fourth contact plug 53 to the wiring 55; a side wall 41 which is disposed on the side surface of the ferroelectric capacitor 30, having a lower end situated at a position upper than the lower plane of the bottom electrode 32 of the ferroelectric capacitor 30; and,

a third contact plug 51 having the upper end connected to the wiring 55 and the lower end connected to the transistor 20 through a second contact plug 29, the third contact plug 51 being in touch with the side wall 41.

As a result of this, since the third contact plug 51 is formed in a self-aligning manner along the side wall 41, the third contact plug 51 has a large matching margin with respect to the ferroelectric capacitor 30, and the defect of the ferroelectric capacitor 30 caused by the short circuit thereof is surely avoided. This can enhance the yield of manufacture of the semiconductor apparatus 1.

The side wall 41 has structure in which the lower end thereof is situated at a position between the top and the bottom electrodes 34 and 32 of the ferroelectric capacitor 30. When compared with the structure in which a side wall has the lower end thereof extends down to the lower plane of the bottom electrode 32 of the ferroelectric capacitor 30, the expansion of the side wall 41 from the vertical center line of the ferroelectric capacitor 30 is small. Therefore, without separating the adjoining ferroelectric capacitors 30, the distance between the side walls 41 thereof is increased. Because it is not necessary to secure the distance between the side walls 41 more than a given value, the adjoining ferroelectric capacitors 30 can be disposed such that they are nearer to each other. As a result of this, while being able to secure the necessary diameter (width) of the third contact plug 51 formed between the adjoining side walls 41 to thereby secure proper resistance, the area to be occupied by a cell can be reduced relatively. That is, higher integration of a cell including the ferroelectric capacitor 30 and the like can be attained. On the other hand, when the area of the ferroelectric capacitor 30 is increased instead of reducing distance between the adjoining ferroelectric capacitors 30, it is also possible to form the semiconductor apparatus 1 with further enhanced reliability.

In the semiconductor apparatus 1 according to the embodiment 1, the lower end of the side wall 41 is positioned at a level between an upper and a lower surfaces of the ferroelectric film 33 as shown in FIG. 1. However, the lower end of the side wall 41 may be positioned at any level between the upper and lower surfaces of the ferroelectric capacitor 30 properly.

The lower end of the side wall 41 may be positioned at a level between an upper and a lower surfaces of the bottom electrode 32. In this case, the expansion of the side wall 41 from the vertical center line of the ferroelectric capacitor 30 becomes larger than that of the structure shown in FIG. 1. Therefore, the risk of the short circuit is surely avoided during forming of the contact hole.

The lower end of the side wall 41 may be positioned at a level between an upper and a lower surfaces of the top electrode 34. In this case, the expansion of the side wall 41 from the vertical center line of the ferroelectric capacitor 30 becomes smaller than that of the structure shown in FIG. 1. Therefore, the adjoining ferroelectric capacitors 30 can be closely disposed. This structure is suitable, for example, when the angle between the side surface of the ferroelectric capacitor 30 and the surface of the semiconductor substrate 11 is almost a right angle.

### Embodiment 2

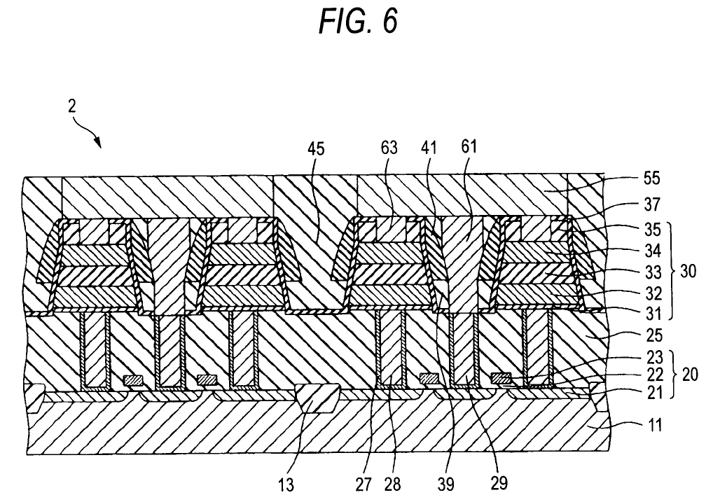

Description will be given below of a semiconductor apparatus and a method for manufacturing a semiconductor apparatus according to an embodiment 2 with reference to FIG. 6. FIG. 6 is a schematic section view of the structure of a semiconductor apparatus according to the embodiment 2. The semiconductor apparatus according to the embodiment 2 is different from the semiconductor apparatus 1 according to the embodiment 1 in that the distance between a ferroelectric capacitor and a wiring is shortened. In the embodiment 2, parts having the same structures as those in the embodiment 1 are given the same designations and thus the description thereof is omitted here.

As shown in FIG. 6, the semiconductor apparatus 2 according to the embodiment 2 is structured such that the aspect (depth/opening width) ratio of a third contact plug 61 for connecting together a second contact plug 29 and a wiring 55 and the aspect ratio of a fourth contact plug 63 for contacting together the top electrode 34 of a ferroelectric capacitor 30 and the wiring 55 are smaller than those in the embodiment 1. The thickness of a third inter-layer insulating film 45 is thin and a third inter-layer insulating film 45 is not provided on the upper portion of an upper film 35. However, the third inter-layer insulating film 45 may also be left thin on the upper portion of the upper film 35. The remaining structures of the semiconductor apparatus 2 are the same as those of the semiconductor apparatus 1 according to the embodiment 1.

Description will be given below of a method for manufacturing the semiconductor apparatus 2 with reference to FIG. 4B. The present method for manufacturing the semiconductor apparatus 2 is similar to the method for manufacturing the semiconductor apparatus 1 according to the embodiment 1 up to the step of forming the third inter-layer insulating film 45 shown in FIG. 4B. The third inter-layer insulating film 45 of the semiconductor apparatus 2 is formed thin when compared with the semiconductor apparatus 1. And, the third inter-layer insulating film 45 is flattened according to a CMP method in such a manner that the third inter-layer insulating film 45 is hardly left on the hydrogen barrier film 37 disposed on the ferroelectric capacitor 30. After the third inter-layer insulating film 45 is formed, the method for manufacturing the semiconductor apparatus 2 is almost similar to the method for manufacturing the semiconductor apparatus 1. However, when the third and fourth contact plugs 61 and 63 are formed respectively, the aspect ratio of the contact hole is reduced, thereby being able to secure the constant shape of the contact hole as well as to reduce the time for forming the contact hole. The following steps are performed similarly to the method for manufacturing the semiconductor apparatus 1 according to the embodiment 1, thereby completing the semiconductor apparatus 2.

As described above, when compared with the semiconductor apparatus 1, the semiconductor apparatus 2 is structured such that the aspect ratios of the third and fourth contact plugs 61 and 63 are small. As a result of this, when compared with the semiconductor apparatus 1, the manufacturing yield of the semiconductor apparatus 2 can be enhanced. The other effects of the semiconductor apparatus 2 are similar to the effects that the semiconductor apparatus 1 according to the embodiment 1 can provide.

### Embodiment 3

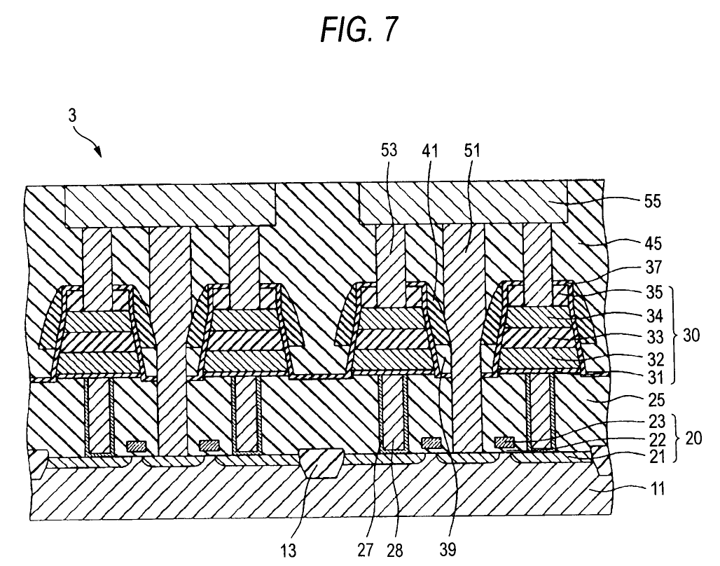

Description will be given below of a semiconductor apparatus and a method for manufacturing a semiconductor apparatus according to an embodiment 3 with reference to FIG. 7. FIG. 7 is a schematic section view of the structure of a semiconductor apparatus according to the embodiment 3. The semiconductor apparatus according to the embodiment 3 is different from the semiconductor apparatus 1 according to the embodiment 1 in that second and third contact plugs are formed integrally at a time. In the embodiment 3, parts having the same structures as those in the embodiment 1 are given the same designations and thus the description thereof is omitted here.

As shown in FIG. 7, the semiconductor apparatus 3 includes an integrally formed consolidated contact plug 71, the consolidated contact plug 71 having the upper end connected to the wiring 55 and the lower end connected to the transistor 20, and being in touched with the sidewall 41. The consolidated contact plug 71 substitutes for the second and third contact plugs 29 and 51 of the semiconductor apparatus 1 according to the embodiment 1. The remaining structures of the semiconductor apparatus 3 according to the embodiment 3 are similar to those of the semiconductor apparatus 1 according to the embodiment 1.

Description will be given below of a method for manufacturing the semiconductor apparatus 3 with reference to FIGS. 2A and 4B. In the semiconductor apparatus 3, there is not provided the second contact plug 29 that is provided in the semiconductor apparatus 1 according to the embodiment 1 shown in FIG. 2A; but, in a state where there is left in the semiconductor apparatus 3 an area for the second contact plug 29 to be provided, the semiconductor apparatus manufacturing operation is performed similarly to the semiconductor apparatus 1 according to the embodiment 1 up to the step of providing the consolidated contact plug 71.

Similarly to the semiconductor apparatus 1 according to the embodiment 1 shown in FIG. 4B, there is formed a patterned mask according to a photolithography method. By using the mask, there is formed a contact hole in such a manner that it penetrates through the third inter-layer insulating film 45, second inter-layer insulating film 39, hydrogen barrier film 37 and first inter-layer insulating film 25. In the contact hole, there is formed a conductive contact plug film (material for forming a contact plug) according to a sputtering method, a CVD method, or the like, whereby there is provided the consolidated contact plug 71 that is connected to the transistor 20. The contact plug film, which constitutes the consolidated contact plug 71, can be made of, for example, W, Al—Cu, polycrystalline silicone, or the like. Since the contact hole is dug along the side wall 41 in an self-aligning manner, even if the contact hole is shifted slightly in position when it is formed according to a photolithography method, such slight position shift can be corrected; and, therefore, similarly to the semiconductor apparatus 1 according to the embodiment 1, the contact hole is formed so as to extend almost in the vertically direction from the lower end portion of the side wall 41. Although the aspect ratio of the contact hole is large, there is formed such consolidated contact plug 71 that is seamlessly formed as a consolidated body by drilling an opening once. The following steps are performed similarly to the semiconductor apparatus 1 according to the embodiment 1, thereby completing the semiconductor apparatus 3. Either the fourth contact plug 53 or consolidated contact plug 71 may be formed first, similarly to the semiconductor apparatus 1 according to the embodiment 1.

As described above, according to the semiconductor apparatus 3, the consolidated contact plug 71 is formed as a consolidated body along the side wall 41 in a self-aligning manner. As a result of this, when compared with the semiconductor apparatus 1 according to the embodiment 1, there is not generated the difference that can be found in the embodiment 1 when the two contact plugs are connected together. Also, there does not occur an increase in the contact resistance between the contact portions of the two contact plugs. Therefore, simply by carrying out one step, there can be formed the consolidated contact plug 71 which is reduced in resistance and is stable. The stabilization of the consolidated contact plug 71 can enhance further the manufacturing yield of the semiconductor apparatus 3. The other effects of the semiconductor apparatus 3 are similar to the effects that are provided by the semiconductor apparatus 1 according to the embodiment 1.

### Embodiment 4

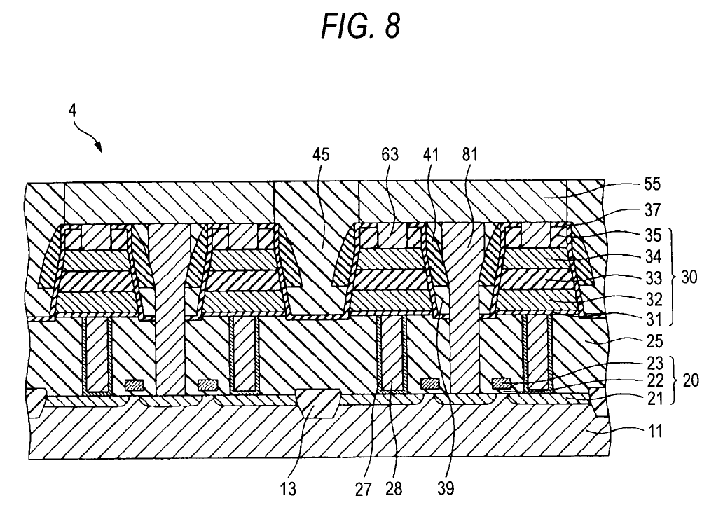

Description will be given below of a semiconductor apparatus and a method for manufacturing a semiconductor apparatus according to an embodiment 4 with reference to FIG. 8. FIG. 8 is a schematic section view of the structure of a semiconductor apparatus according to the embodiment 4. The semiconductor apparatus 4 according to the embodiment 4 has a structure consisting of a combination of the semiconductor apparatus 2 according to the embodiment 2 and the semiconductor apparatus 3 according to the embodiment 3. In the embodiment 4, parts having the same structures as those in the embodiments 1 to 3 are given the same designations and thus the description thereof is omitted here.

As shown in FIG. 8, according to the semiconductor apparatus 4, a consolidated contact plug 81 having an upper end connected to the wiring 55 and a lower end connected to the transistor 20 and being in touch with the side wall 41, and a fourth contact plug 63 for connecting the top electrode 34 of the ferroelectric capacitor 30 to the wiring 55 are respectively formed short, while the thickness of the third inter-layer insulating film 45 is formed small. The remaining structures of the semiconductor apparatus 4 are similar to that of the semiconductor apparatus 1 according to the embodiment 1.

Description will be given below of a method for manufacturing the semiconductor apparatus 4 with reference to FIG. 4B. The present method for forming the consolidated contact plug 81 up to the state shown in FIG. 4B is similar to the method for forming the consolidated contact plug 71 in the semiconductor apparatus 3 according to the embodiment 3. Also, similarly to the semiconductor apparatus 2 according to the embodiment 2, the third inter-layer insulating film 45 is formed thin; and, in the third inter-layer insulating film 45, similarly to the semiconductor apparatus 3 according to the embodiment 3, the consolidated contact plug 81 is formed as a consolidated body along the side wall 41 in a self-aligning manner. The following steps of the present embodiment are performed similarly to the semiconductor apparatus 2 according to the embodiment 2, thereby completing the semiconductor apparatus 4.

As described above, in the semiconductor apparatus 4, the consolidated contact plug 81 formed as a consolidated body along the side wall 41 in a self-aligning manner and the fourth contact plug 63 are respectively formed further shorter similarly to the semiconductor apparatus 2 according to the embodiment 2. As a result of this, when compared with the semiconductor apparatus 3 according to the embodiment 3, the aspect ratio of the consolidated contact plug 81 is small. Therefore, a contact hole and a contact plug can be formed easily, that is, the contact hole can be formed with a higher manufacturing yield. When compared with the semiconductor apparatus 2 and 3 respectively according to the embodiments 2 and 3, the semiconductor apparatus 4 can be enhanced further in the manufacturing yield thereof. The other effects of the semiconductor apparatus 4 are similar to those of the semiconductor apparatus 1 to 3 respectively according to the embodiments 1 to 3.

### Embodiment 5

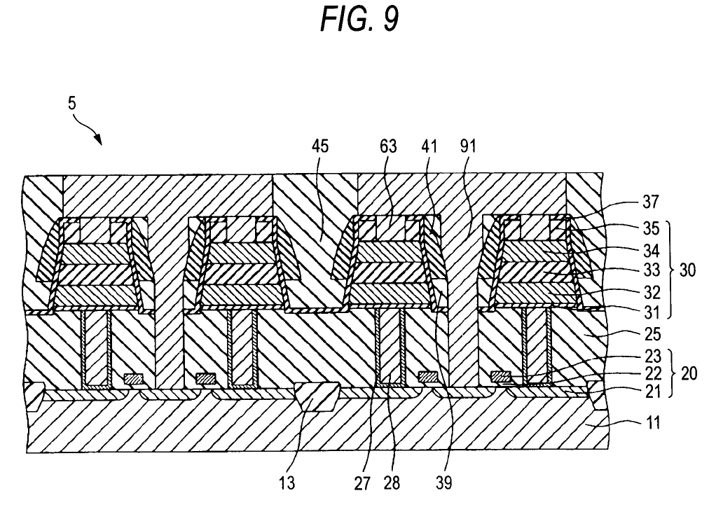

Description will be given below of a semiconductor apparatus and a method for manufacturing a semiconductor apparatus according to an embodiment 5 with reference to FIG. 9. FIG. 9 is a schematic section view of the structure of a semiconductor apparatus according to the embodiment 5. The semiconductor apparatus 5 according to the embodiment 5 is different from the semiconductor apparatus 4 according to the embodiment 4 in that the contact plug and wiring are formed as a consolidated body. In the embodiment 5, parts having the same structures as those in the embodiments 1 to 4 are given the same designations and thus the description thereof is omitted here.

As shown in FIG. 9, the semiconductor apparatus 5 includes an integrally formed consolidated contact plug wiring portion 91 instead of the consolidated contact plug 81 and wiring 55 provided in the semiconductor apparatus 4 according to the embodiment 4. The other structures of the semiconductor apparatus 5 are similar to those of the semiconductor apparatus 4 according to the embodiment 4.

Description will be given below of a method for manufacturing the semiconductor apparatus 5 with reference to FIG. 5. The steps of the present method prior to formation of the consolidated contact plug wiring portion 91 are similar to the steps of the method for manufacturing the semiconductor apparatus 4 according to the embodiment 4 prior to formation of the contact plug 81 and contact plug 63. In the semiconductor apparatus 5, the fourth contact plug 63 is formed first and, after then, the third inter-layer insulating film 45 is flattened according to a CMP method; and, by using a mask, a contact hole is formed in the third inter-layer insulating film 45, second inter-layer insulating film 39, hydrogen barrier film 37 and first inter-layer insulating film 25 (see FIG. 5). The contact hole is formed along the sidewall 41 in a self-aligning manner. In the contact hole and on the third inter-layer insulating film 45, there is formed a conductive contact plug wiring film (material for forming a contact plug and a wiring) according to a sputtering method, a CVD method, or the like. After formation of the contact plug wiring film, the steps similar to a generally used semiconductor manufacturing method are performed, thereby completing the semiconductor apparatus 5. The contact plug wiring film can be made of, for example, W, Al—Cu, polycrystalline silicone, or the like.

As described above, the semiconductor apparatus 5 includes the consolidated contact plug wiring portion 91 in which the third contact plug and wiring are consolidated into a consolidated body. The semiconductor apparatus 5 can provide such effects that the semiconductor apparatus 4 according to the embodiment 4 can provide and, in addition to this, when compared with the semiconductor apparatus 1 to 4 respectively according to the embodiments 1 to 4, it allows the reduction of the manufacturing steps thereof owing to the consolidated structure of the consolidated contact plug wiring portion 91.

As a modification 1 of the present embodiment, the fourth contact plug 63 and wiring 55 in the semiconductor apparatus 4 according to the embodiment 4 can be formed as a consolidated body. In this case, the consolidated contact plug 81 is formed separately from the fourth contact plug 63 and wiring 55.

As modifications 2 and 3 of the present embodiment, either the third contact plug 51 or fourth contact plug 53 and the wiring 55 in the semiconductor apparatus 1 according to the embodiment 1 can be consolidated into a consolidated body.

As modifications 4 and 5 of the present embodiment, either the third contact plug 61 or fourth contact plug 63 and the wiring 55 in the semiconductor apparatus 2 according to the embodiment 2 can be consolidated into a consolidated body.

As modifications 6 and 7 of the present embodiment, either the third contact plug 71 or fourth contact plug 53 and the wiring 55 in the semiconductor apparatus 3 according to the embodiment 3 can be consolidated into a consolidated body.

According to the above-mentioned modifications 1 to 7 of the present embodiment, there can be provided effects similar to those of the semiconductor apparatus according to their corresponding embodiments. Also, when compared with the semiconductor apparatus according to their corresponding embodiments, the steps of manufacturing the respective modifications can be reduced owing to the consolidated structure of the contact plug wiring portion.

The invention is not limited to the above-mentioned embodiments but various changes and modifications are possible without departing from the subject matter of the invention.

For example, the semiconductor apparatus may have a structure in which two adjoining memory cells are formed so that the two ferroelectric capacitors thereof share one bottom electrode. In the above-mentioned structure, by appropriately adjusting the position of the lower end of the side wall as the embodiments, high integration density of memory cells and high fabrication yield can be accomplished.

According to an aspect of the present invention, there is provided a semiconductor apparatus in which diameter (width) of a contact plug that connects the top electrode with the diffusion layer formed on the substrate and that is formed in a self-aligning manner is kept wide, and a method for manufacturing the semiconductor apparatus.

What is claimed is:

1. A semiconductor apparatus comprising:
a semiconductor substrate;
a transistor including:
a first diffusion layer formed on the semiconductor substrate, and
a second diffusion layer formed on the semiconductor substrate;
a ferroelectric capacitor including:
a bottom electrode connected to the first diffusion layer,
a ferroelectric film formed on the bottom electrode, and
a top electrode formed on the ferroelectric film;
a side wall disposed on a side surface of the ferroelectric capacitor, the side wall having a lower end positioned upper than a bottom plane of the ferroelectric capacitor; and
a contact plug connected to the second diffusion layer and to the top electrode, the contact plug being in touch with the side wall.

2. The semiconductor apparatus according to claim 1 further comprising:
a first interlayer insulating film formed on the semiconductor substrate and under the ferroelectric capacitor; and
a second interlayer insulating film formed on the first interlayer insulating film and under the lower end of the side wall.

3. The semiconductor apparatus according to claim 1,
wherein the contact plug includes two parts;
wherein a lower part of the contact plug is connected to the second diffusion layer;
wherein an upper part of the contact plug formed on the lower contact plug; and
wherein the upper contact plug is in touch with the side wall.

4. The semiconductor apparatus according to claim 1 further comprising:
a wiring connected to the top electrode;
wherein the contact plug is connected to the top electrode through the wiring.

5. The semiconductor apparatus according to claim 4,
wherein the ferroelectric capacitor further includes:
an upper film formed on the top electrode, and
a reaction preventive insulating film formed on the upper film; and
wherein the wiring is in touch with the reaction preventive insulating film.

6. The semiconductor apparatus according to claim 1,
wherein the contact plug is seamlessly formed of the same material therethrough.

7. The semiconductor apparatus according to claim 1,
wherein the contact plug includes:
a contact plug portion being in touch with the side wall, and
a wiring portion extend from an upper end of the contact plug portion to be connected to the top electrode; and
wherein the contact plug portion and the wiring portion are formed of the same material therethrough.

8. The semiconductor apparatus according to claim 1,
wherein the lower end of the sidewall is positioned between an upper and a lower surfaces of the ferroelectric film.

9. The semiconductor apparatus according to claim 1,
wherein the lower end of the sidewall is positioned between an upper and a lower surfaces of the bottom electrode.

10. The semiconductor apparatus according to claim 1,
wherein the lower end of the sidewall is positioned between an upper and a lower surfaces of the top electrode.

11. A method for manufacturing a semiconductor apparatus, the method comprising:
forming a transistor having a first and a second diffusion layers on a semiconductor substrate;
forming a first interlayer insulating film on the semiconductor substrate;
forming a first and a second contact plugs respectively connected to the first and the second diffusion layers and disposed in the first interlayer insulating film;
forming a ferroelectric capacitor having a reaction preventive film disposed on the first interlayer insulating film and connected to the first contact plug, a bottom electrode formed on the reaction preventive film, a ferroelectric film formed on the bottom electrode, a top electrode formed on the ferroelectric film, and an upper film formed on the top electrode, by:
sequentially forming a reaction preventive film material, a bottom electrode material, a ferroelectric film material, a top electrode material and an upper film material, on the first interlayer insulating film,
patterning the upper film material so as to be used as a mask, and
performing an etching process using the mask;
forming a reaction preventive insulating film on the whole surface where the ferroelectric capacitor is formed;
forming a second interlayer insulating film on the reaction preventive insulating film;
adjusting the second interlayer insulating film so that a top surface thereof is situated at a level between an upper and a lower surfaces of the ferroelectric capacitor and so that the second interlayer insulating film is hardly left on the top electrode by performing a first etching-back process;
forming a side wall material on the whole surface where the first etching-back process is performed;
forming a side wall on a side surface of the ferroelectric capacitor by performing a second etching-back process;
forming a third interlayer insulating film on the whole surface where the second etching-back process is performed; and
forming a third contact plug connected to the second contact plug in the third interlayer insulating film, the third contact plug being in touch with the side wall.

12. The method according to claim 11,
wherein the first etching-back process adjusts the second interlayer insulating film so that the top surface thereof is situated at a level between an upper and a lower surfaces of the ferroelectric film.

13. The method according to claim 11,
wherein the first etching-back process adjusts the second interlayer insulating film so that the top surface thereof is situated at a level between an upper and a lower surfaces of the bottom electrode.

14. The method according to claim 11,
wherein the first etching-back process adjusts the second interlayer insulating film so that the top surface thereof is situated at a level between an upper and a lower surfaces of the top electrode.
